(19) United States
(12) Patent Application Publication
(10) Pub. No.: US 2010/0236035 A1
(43) Pub. Date: Sep. 23, 2010

(54) SYSTEM AND METHOD FOR DETECTING DEFECTS IN A SOLAR CELL AND REPAIRING AND CHARACTERIZING A SOLAR CELL

(76) Inventor: Kyo Young Chung, San Jose, CA (US)

Correspondence Address: Kyo Young Chung, 6838 Westmoor Way, San Jose, CA, 95129, US

(21) Appl. No.: 12/407,737

(22) Filed: Mar. 19, 2009

(51) Int. Cl. H01L 31/18; G01R 31/308; G01N 27/00

(52) U.S. Cl. 29/25.01; 438/4; 324/501; 324/71.5

(57) ABSTRACT

A system and method for detecting a defect in a solar cell and repairing and characterizing a solar cell includes applying a test signal to the solar cell, monitoring the response of solar cell, detecting a defect associated with its location during the monitoring step, removing or isolating the defect from a solar cell and characterizing solar cell performance. The defect may be a short between the emitter and the base of solar cell. The system and method also detect a precise location of the defect based on the use of light valve panel (LVP), which can control the input beam to or output beam from the solar cell in terms of size, position, gray level, and wavelength of the transmitted light. The LVP may be realized in any one of a variety of ways. For example, the active matrix liquid crystal display (AMLCD) such as Thin Film Transistor driven LCD (TFT-LCD) may be used as the LVP.

### BACKGROUND OF THE INVENTION

1. Field of the Invention

This invention generally relates to testing and repairing electronic circuits, and more particularly to a system and method for detecting defects in a solar cell and repairing and characterizing the circuits which include one or more solar cells.

2. Background of the Related Art

Solar cell is one of the promising ones among the renewable energy resources as an alternative to fossil fuels. A large barrier against the commercial expansion of the solar cell, however, is the high price of the solar-cell module, which may be caused by low yield of solar cell manufacturing.

During the manufacturing process of solar cell, defects may develop which, if left un-repaired, may diminish the number of working units and degrade the conversion efficiency of solar cell and/or reduce the manufacturing yield. These defects include electrical shorts between the top electrode, which is also called as the emitter, and the bottom electrode, which is also called as the base.

Once a defect like the short between the emitter and the base has been located in a solar cell, it can be repaired by removing or isolating the short and making the rest of solar cell area functional.

In order to monitor the manufacturing process of solar cell, one needs to characterize the performance of solar cell on various locations of solar cell.

In view of the foregoing considerations, it is apparent that there is a need for a system and method for applying the test signals to solar cell, monitoring measurement characteristics, characterizing solar cell performance, detecting the existence of a defect in a solar cell, finding the location of the defect, and repairing the solar cell without disturbing other portions of the solar cell that are properly functioning. The need to automatically test and repair the defects becomes more important as the number and size of solar cells increase on a substrate.

### SUMMARY OF THE INVENTION

An object of the present invention is to improve the accuracy and efficiency of testing and repairing electronic circuits including ones containing solar cells.

Another object of the present invention is to provide a system and method for accurately detecting defects in a solar cell.

Another object of the present invention is to provide a system and method for precisely determining the location of a defect in a solar cell during a testing procedure.

Another object of the present invention is to provide a system and method for repairing a solar cell by removing or isolating the detected defect during a repairing procedure.

Another object of the present invention is to provide a system and method for characterizing a solar cell.

These and other objects and advantages of the present invention are achieved by providing the method for detecting a defect in solar cell which, in accordance with one embodiment, includes applying test signals to the solar cell, monitoring the optical or electrical responses of solar cell, detecting a defect with its location during the monitoring step, repairing the defect of solar cell, and characterizing a solar cell.

The defect may be a short between the emitter and the base of solar cell. The test signal may be an electrical signal applied between the emitter and the base of solar cell to generate electroluminescence from normal part of solar cell and candescent light from highly conducting part such as a short defect between the emitter and the base of solar cell. The test signal also may be an optical beam illuminated on the solar cell surface to generate photo-generated current by normal function of solar cell. The method further includes finding a location of the defect based on the measurement of abnormal luminance/luminescence or photo-generated current in relation with its coordinate on solar cell. The position-dependent luminance/luminescence or photo-generated current of solar cell may be measured in any one of variety of ways. For example, the luminance/luminescence may be measured by a camera which has an array of sensors sensitive to the measured signal wavelength or frequency. The position-dependent luminance/luminescence may also be measured by using a simple aerial sensor and the light valves in a matrix format. The light generated from the solar cell surface through luminance/luminescence of solar cell or the optical beam illuminated on the solar cell front surface to generate photo-generated current may go through the light valves in a matrix format. The light valves in a matrix format can give the capability of position-dependent light passage.

The method further includes repairing the solar cell by removing or isolating the defect from normal portion of solar cell. The removing or isolating defects may be performed in any one of variety of ways. For example, laser beam can be used to remove or isolate the defect when scanning capability of either laser head or solar cell under test is provided. Or the removing the short defect between the emitter and the base of solar cell can be done by sending current between two electrodes, preferably in the reverse direction of solar cell to increase the maximum current to the defect because the electrical signal applied to solar cell in forward direction of solar cell can experience limitation of applied voltage due to low forward threshold voltage of solar cell and this may limit the current increase through the defect. The current sent to solar cell in reverse direction can be directed to the short defect and the heat generated by the current flow can remove the defect. In order to reduce the amount of current flow, one can also use the heat from the additional light beam, which can be either applied to entire solar cell surface or selectively to the defect area using the light valves in a matrix format.

The method further includes characterizing the solar cell by combining the light valves in a matrix format with the solar cell characterizing methods such as current-voltage measurement, spectral response measurement, or quantum efficiency measurement. The light valves in a matrix format can enhance those characterizing methods by providing light passage control functions with the control factors such as the size, location, gray level, and color of test beam.

In accordance with another embodiment, the present invention is a system for detecting the defect in solar cells and repairing and characterizing a solar cell. The system includes a signal generator for applying test signals to the solar cell, a monitor for monitoring the optical or electrical responses of solar cell, a detector for detecting defects and their locations associated with light transmittance control during said monitoring step, and a characterizer characterizing a solar cell. The test signal may be an electrical signal applied between the emitter and the base of solar cell to generate electroluminescence from normal part of solar cell and candescent light from highly conducting part such as a short defect between the emitter and the base of solar cell. The test signal also may be an optical beam illuminated on the solar cell front surface to generate photo-generated current by normal function of solar cell. The detector further includes detecting a location of the defect based on the measurement of abnormal luminance/luminescence or photo-generated current in relation with its coordinate on solar cell. The position-dependent luminance/luminescence or photo-generated current of solar cell may be measured in any one of variety of ways. For example, the luminance/luminescence may be measured by a camera which has an array of sensors sensitive to the measured signal wavelength or frequency. The position-dependent luminance and luminescence may be measured by using a simple aerial sensor and the light valves in a matrix format. The light generated from the solar cell surface through luminance/luminescence or the optical beam illuminated on the solar cell front surface to generate photo-generated current may go through the light valves in a matrix format. The light valves in a matrix format can give the capability of position-dependent light passage.

In accordance with another embodiment, the present invention is a signal analyzer for testing solar cells. The signal analyzer includes probes for inputting electrical signals into the solar cell or outputting photo-generated current, a camera, current-voltage measurement unit and a processor which monitors luminance/luminescence or photo-generated current of solar cell and detects a location of the defect based on the measurement of abnormal luminance/luminescence or photo-generated current in relation with its coordinate on solar cell. The signal analyzer may detect any of the types of defects previously mentioned, using one or more of the previously mentioned techniques.

Additional advantages, objects, and features of the invention will be set forth in part in the description which follows and in part will become apparent to those having ordinary skill in the art upon examination of the following or may be learned from practice of the invention. The objects and advantages of the invention may be realized and attained as particularly pointed out in the appended claims.

### BRIEF DESCRIPTION OF THE DRAWINGS

The invention will be described in detail with reference to the following drawings in which like reference numerals refer to like elements wherein:

FIG. 1 is a block diagram of the test and repair apparatus illustrating a structure including a light valve panel, in accordance with the present invention;

FIG. 2 is a solar cell current-voltage characteristic when the solar cell is illuminated;

FIG. 3 is a simple view of a cross section of TFT-LCD panel;

FIG. 4 is a simple top view of a part of TFT back plane;

FIG. 5 is a flow chart of solar cell test, in accordance with the present invention;

FIG. 6 is an equivalent circuit of a solar cell;

FIG. 7 is an exemplary cross-section of a solar cell whose defect is isolated;

FIG. 8 is an example of spectral response of solar cell

### DETAILED DESCRIPTION OF PREFERRED EMBODIMENTS

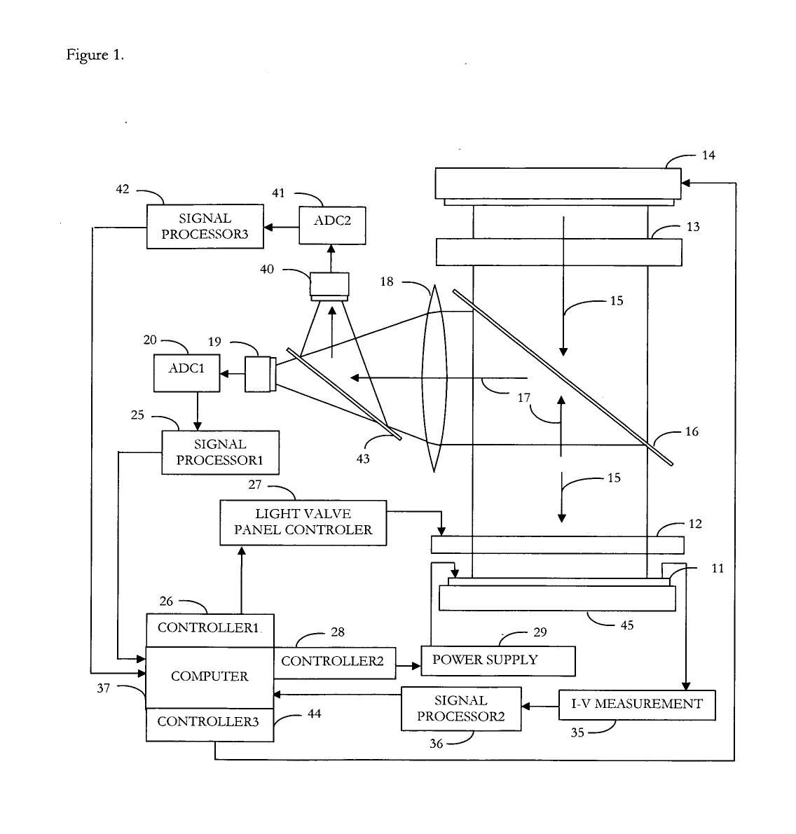

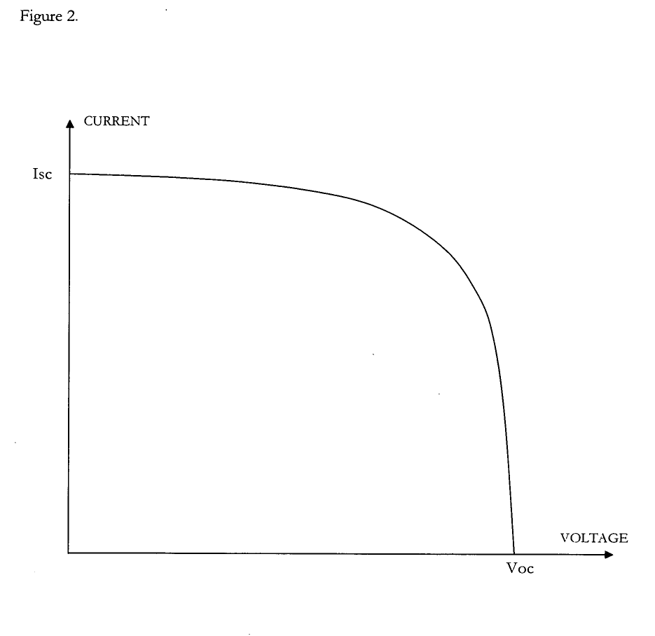

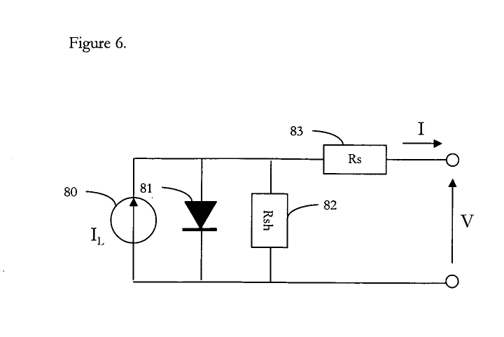

FIG. 1 is a block diagram of the test apparatus illustrating a structure to test and repair solar cells. A solar cell is tested after manufacturing process is completed to give functionality of current generation when the surface of solar cell receives light. In the FIG. 1 the solar cell under test (SUT) 11 may be tested in two modes, independently or in serial modes. The SUT can receive the optical input beam 15, which is generated by the optical energy source 14 and goes through the light valve panel (LVP) 12. The optical input beam 15, if necessary for collimation of light, may be expanded and collimated by the beam expander 13. If the SUT has no defect and works properly, then it generates photo-induced current and the I-V (current-voltage) measurement unit 35 measures the current-voltage characteristic as shown in FIG. 2, where Isc and Voc stand for a short circuit current and an open circuit voltage, respectively. FIG. 6 shows the equivalent circuit of a solar cell, where a solar cell is represented by a current source 80, a diode 81, a shunt resistor 82, and a series resistor 83. When there is a process anomaly and process defect is created, then the measured I-V characteristic shows abnormal measurement data such as low Isc, low Voc, high series resistance, low shunt resistance, and/or large deviation of curve slopes near Isc and/or Voc from normal slopes, which ideally show almost vertical crossings at the x and y axes. The measurement data is delivered to the computer 37 through the signal processor 36, which communicates with the computer 37 and the I-V measurement unit 35.

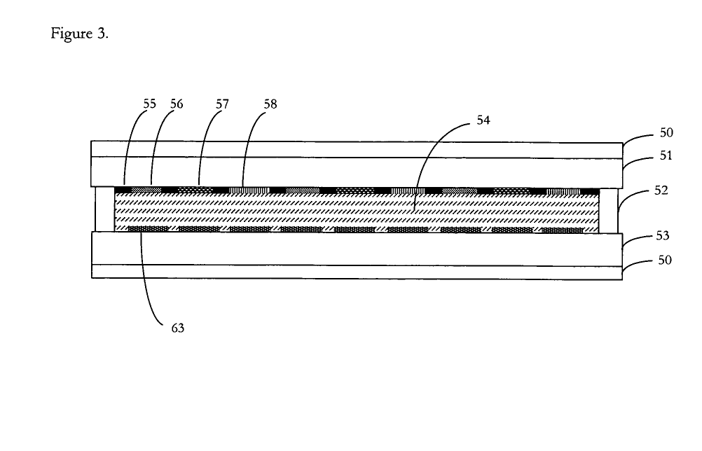

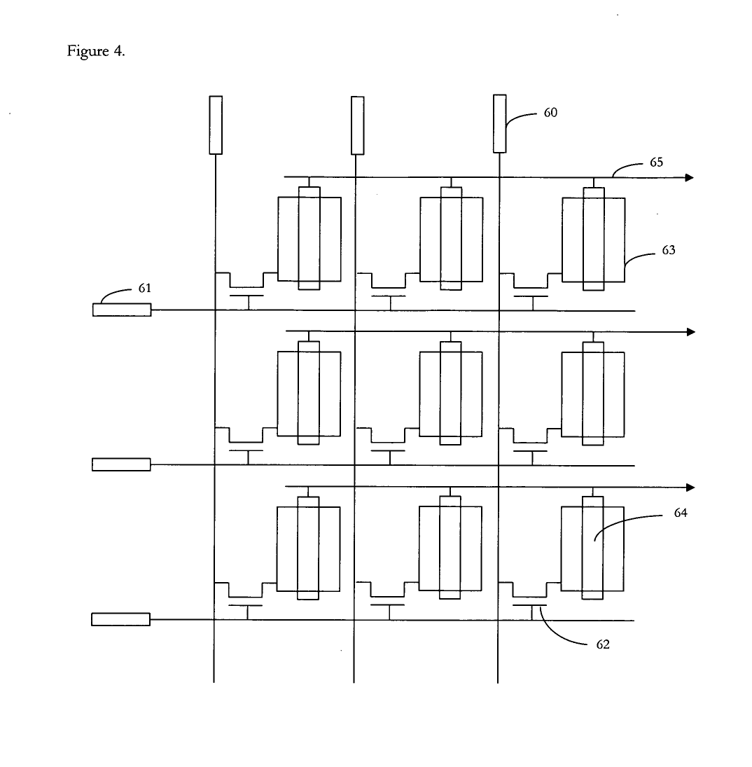

The presence of a defect in a solar cell can be detected by observing whether the measured solar cell performance parameters such as Isc, Voc, series resistance, shunt resistance, the curve slopes, and the fill factor which is defined as the ratio (the maximum value of CURRENT*VOLTAGE)/(Isc*Voc) in FIG. 2 are beyond certain criteria. The solar cell with a defect such as a short defect between an emitter and a base can be repaired by removing or isolating the defect from the normal portion of solar cell. However, in order to repair the defect, one needs to find the location of the defect and position identifying method is required. The LVP can provide the position identifying method if the LVP has the capability of matrix-driven light control. For example, the panel used for passive matrix driven liquid crystal display (PMLCD) or active matrix driven liquid crystal display (AMLCD) such as Thin Film Transistor driven LCD (TFT-LCD) or Diode driven LCD has the capability of controlling the light passage in very small size unit, which is called a pixel, in a matrix format. FIG. 3 shows a simple view of a cross section of TFT-LCD panel, where the color filter front plane 51 has a black matrix 55 which blocks the light and a patterned color filter array which is composed of an array of red color dot 56, an array of green color dot 57, and an array of blue color dot 58, the TFT back plane 53 has an array of transparent pixel electrode 63 and TFT and storage capacitor, which are 62 and 64 respectively in FIG. 4, the sealant 52 confines the liquid crystal 54 between the color filter plane and TFT back plane, and the polarizer 50 is attached to the color filter plane and TFT back plane. FIG. 4 shows a simple top view of a part of TFT back plane, where the pad for data line 60, the pad for gate line 61, the TFT 62, the transparent pixel electrode 63, the storage capacitor 64, and the common line 65 are shown. The TFT-LCD panel can control the light passage through its pixel electrodes with control factors such as the position and number of pixels, the gray scale, and color. Thus, initial test to determine the presence of a defect in solar cell can be done with all the pixel electrodes transmitting the light with full intensity. The color filter array on the color filter front plane 51 may not be necessary and absent as in the case where color is not needed but higher light intensity is required. If defect presence is decided, then another test can be performed to find the defect location varying the control factors. A solar cell can be, in general, divided into multiple smaller solar cells with electrical resistance among their electrodes especially on the front surface where the resistance value can be high compared to the back surface. For example, the solar cell can be divided into four quadrants and the optical input beam is applied to the solar cell surface by the unit of quadrant by having the LVP transmit the light by quadrant and the current (-voltage) characteristic is measured for each quadrant to decide which quadrant contains the defect. The quadrant that has the defect will show the measurement of the worst solar cell performance of light-to-current conversion among the four quadrants. This division of solar cell can be done down to each pixel unit because the TFT-LCD panel has a capability to drive each individual pixel.

In another mode of operation electroluminescence of normal part of solar cell and luminance of abnormal part carrying high current caused by a defect such as the short between an emitter and a base of solar cell can be used for defect detection of solar cell. The electrical signal is applied between an emitter and a base of solar cell from the power supply unit 29, which is controlled by the computer through the controller 28. The light beam generated from the solar cell can be transmitted to the optical sensor 19 and/or the optical sensor 40 through the LVP 12 and the focusing lens 18. The choice of the light beam's route depends on its wavelength and the wavelength characteristic of the filter mirror 43. The output of optical sensor 19 (40) is delivered to the computer through the ADC (analog to digital converter) 20 (41) and the signal processor 25 (42). If there is no defect in solar cell, then the light beam generated from solar cell has expected intensity and frequency from normal electroluminescence. If there is a defect in the solar cell, then the light beam generated from solar cell does not have the intensity and frequency from normal electroluminescence but has the intensity and frequency specific to the defect kind such as a short defect between an emitter and a base of solar cell. Thus, the optical sensors generate different output signals from normal signals when there is a defect in solar cell because its output signal depends on the intensity and wavelength of sensed light. Thus, the presence of a defect in a solar cell can be detected by observing whether the output intensity of the optical sensor that has sensing characteristic tuned to normal electroluminescence of solar cell is above certain criteria and the output intensity of the optical sensor that has sensing characteristic tuned to abnormal luminescence of solar cell is below certain criteria. In order to repair the defect, one needs to find the location of the defect and position identifying method is required. The position-dependent luminance and electroluminescence of solar cell may be measured by a camera which has a sensor array sensitive to the measured signal wavelength and is used to take the image of luminescence and electroluminescence of solar cell. The position-dependent luminance and electroluminescence may also be measured by using a simple aerial sensor and the LVP. The LVP can provide the position identifying method if the LVP has the capability of matrix-driven light control as described above. Thus, initial test to determine the presence of a defect in solar cell can be done with all the pixels transmitting the light with full intensity. If defect presence is decided, then another test can be performed to find the defect location varying the control factors of the LVP. For example, the solar cell can be divided into four quadrants and the optical output beam from the solar cell surface is transmitted to the optical sensors by the unit of quadrant by having the LVP transmit the light by quadrant and the light intensity is measured for each quadrant to decide which quadrant contains the defect. The quadrant that has a defect such as a short defect between the emitter and the base will show the measurement of the lowest solar cell electroluminescence and the highest luminance from the short defect. This division of solar cell can be done down to each pixel unit because the TFT-LCD panel has a capability to drive each individual pixel as described above.

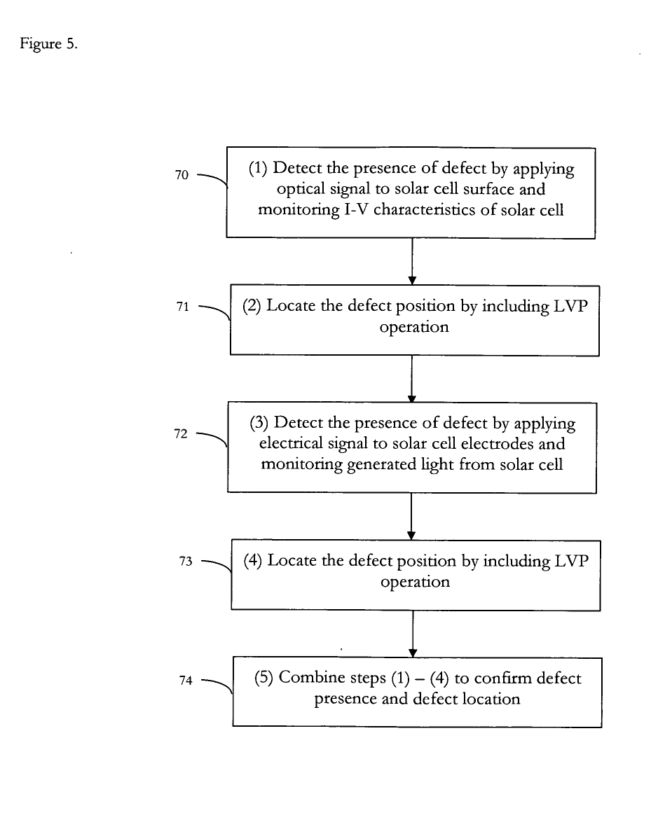

The defect detection and finding the defect location in solar cell can be performed in two modes of operation as described above; one mode is to apply the optical beam to the solar cell surface through the LVP and monitor the current (-voltage) characteristics and another mode is to apply the voltage signal between an emitter and a base of solar cell and monitor the generated light beam by solar cell that goes through the LVP. These two modes of operation can be done independently or in series to generate individual test results and one can combine those individual test results to yield new test result with better defect detection performance and accuracy. FIG. 5 shows an exemplary flow chart of solar cell test using the two modes of operation.

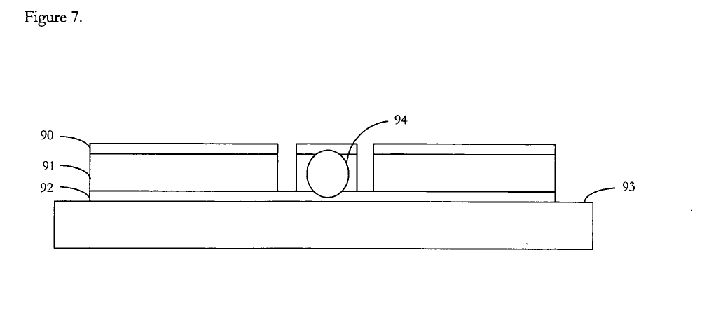

Once the defect location is identified in solar cell, one can repair the solar cell by removing or isolating the defect from normal portion of solar cell as shown in FIG. 7, where a short defect 94 connects a top electrode 90 to a bottom electrode 92 on a substrate 93 through a solar cell semiconductor layer 91. In this example the defect isolation is achieved by cutting the top electrode and the semiconductor layer around the defect. The removing or isolating defects may be performed in any one of variety of ways. For example, laser beam can be used to remove or isolate the defect when scanning capability of either laser head or solar cell under test is provided. Or the removing the short defect between the emitter and the base of solar cell can be done by sending current from the power supply unit 29 between two electrodes, preferably in the reverse direction of solar cell to increase the maximum current to the defect because the electrical signal applied to solar cell in forward direction of solar cell can experience limitation of applied voltage due to low forward threshold voltage of solar cell and this may limit the current increase through the defect. The current sent to solar cell in reverse direction can be directed to the short defect and the heat generated by the current flow can remove the defect. In order to reduce the amount of current flow, one can also use the heat from the additional light beam, which can be either applied to entire solar cell surface or selectively to the defect area using the LVP 12. The optical energy source 14 or another optical energy source with optical guide may be used for this purpose if its output intensity can be controlled by the computer 37 through the controller 44 to provide the required heat for repairing defected solar cell. Additional heat may be applied to the solar cell by raising the temperature of the plate on which the solar cell is placed.

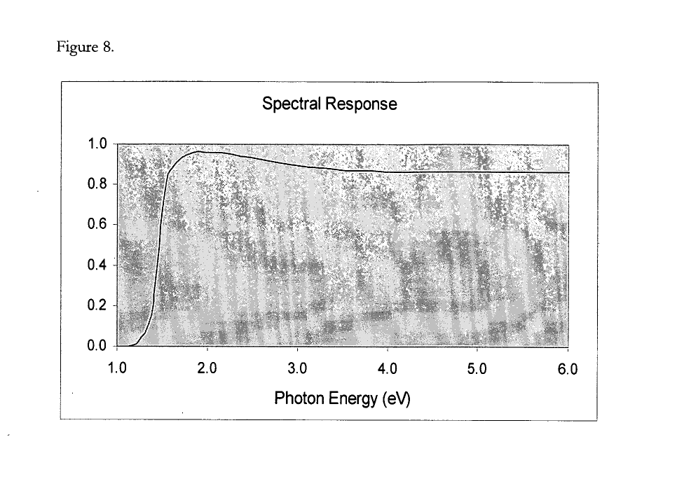

Characterization of solar cell performance includes such methods as current-voltage measurement, spectral response measurement, and quantum efficiency measurement and their characterizing performance may be improved by adding the LVP in the measurement setup, where the LVP's control factors such as the size, position, gray level, and color of the passing test beam can be varied. For example, the solar cell can be divided into four quadrants and the optical input beam is applied to the solar cell surface by the unit of quadrant by having the LVP transmit the light by quadrant and the current-voltage characteristic is measured for each quadrant to decide the variation of current-voltage characteristic from quadrant to quadrant. This division of solar cell can be done down to each pixel unit because the TFT-LCD panel has a capability to drive each individual pixel. For the current-voltage characteristic measurement, the optical energy source 14 in FIG. 1 may be replaced by a solar simulator which is a light source simulating solar radiation. One may also improve the characterizing performance of the spectral response measurement by adding the LVP in the measurement setup. Spectral response of solar cell shows solar cell's light-to-current conversion efficiency with respect to photon's energy as shown in FIG. 8. For example, the solar cell can be divided into four quadrants and the optical input beam is applied to the solar cell surface by the unit of quadrant by having the LVP transmit the light by quadrant and the spectral response is measured for each quadrant to decide the variation of spectral response from quadrant to quadrant. For the spectral response measurement, the optical energy source 14 in FIG. 1 needs to be replaced by another unit that can provide monochrometer and the I-V measurement unit 35 needs to be replaced by another unit that includes lock-in amplifier.

I claim:

1. A method for measuring the photocurrent of a solar cell, comprising:
applying light to a solar cell surface through a light valve panel which controls in a matrix format the transmittance of the light from an optical signal source; and
measuring the photocurrent of the solar cell in response to the controlled light applied through the light valve panel.

2. The method of claim 1, wherein the light valve panel is active matrix liquid crystal display panel.

3. The method of claim 1, wherein the optical signal source and the light valve panel are realized by TFT-LCD.

4. The method of claim 1, wherein the light valve panel controls the light passage in divisions.

5. The method of claim 4, wherein the divisional control of the light valve panel controls the size of light passage.

6. The method of claim 4, wherein the divisional control of the light valve panel controls the position of light passage.

7. The method of claim 1, wherein the light valve panel controls the light passage by intensity.

8. The method of claim 1, wherein the light valve panel controls the light passage by color.

9. The method of claim 1 further comprising, wherein detecting presence of a defect in the solar cell is performed by finding abnormal characteristic such as abnormally low photocurrent in response to the light controlled by the light valve panel.

10. The method of claim 1 further comprising, wherein characterizing the light-to-current conversion performance of solar cell is performed by correlating the measured characteristic such as photocurrent with the light controlled by the light valve panel.

11. The method of claim 1 further comprising, wherein finding the location of the defect in the solar cell is performed by correlating the measured abnormal characteristic such as abnormally low photocurrent with the light controlled by the light valve panel in terms of the position and the size of light passage.

12. The method of claim 11, wherein the defect is a short between the emitter and the base of solar cell.

13. A system for measuring the photocurrent of a solar cell, comprising:
a signal generator which applies an optical signal toward a solar cell surface;
a light valve panel which controls in a matrix format the transmittance of the optical signal to the solar cell surface; and
a monitor which monitors the photocurrent of the solar cell generated in response to the controlled optical signal applied through the light valve panel.

14. The system of claim 13, wherein the light valve panel is active matrix liquid crystal display panel.

15. The system of claim 13, wherein the optical signal generator and the light valve panel are realized by TFT-LCD.

16. The system of claim 13, wherein the light valve panel controls the light passage in divisions.

17. The system of claim 16, wherein the divisional control of the light valve panel controls the size of light passage.

18. The system of claim 16, wherein the divisional control of the light valve panel controls the position of light passage.

19. The system of claim 13, wherein the light valve panel controls the light passage by intensity.

20. The system of claim 13, wherein the light valve panel controls the light passage by color.

21. The system of claim 13 further comprising, wherein detecting presence of a defect in the solar cell is performed by finding abnormal characteristic such as abnormally low photocurrent in response to the optical signal controlled by the light valve panel.

22. The system of claim 13 further comprising, wherein characterizing the light-to-current conversion performance of solar cell is performed by correlating the measured characteristic such as photocurrent with the optical signal controlled by the light valve panel.

23. The system of claim 13 further comprising, wherein finding the location of the defect in the solar cell is performed by correlating the measured abnormal characteristic such as abnormally low photocurrent with the optical signal controlled by the light valve panel in terms of the position and the size of light passage.

24. A means for measuring the photocurrent of a solar cell, comprising:
a first means which applies light to a solar cell surface through a light valve panel which controls in a matrix format the transmittance of the light from an optical signal source; and
a second means which measures the photocurrent of the solar cell in response to the controlled light applied through the light valve panel.

25. A computer-readable medium for storing a program for measuring the photocurrent of a solar cell, said program comprising:
a first code section which controls light to a solar cell surface through a light valve panel which controls in a matrix format the transmittance of the light from an optical signal source; and
a second code section which controls measuring the photocurrent of the solar cell in response to the controlled light applied through the light valve panel.
